(19) United States
(12) Patent Application Publication
(10) Pub. No.: US 2024/0120455 A1
(43) Pub. Date: Apr. 11, 2024

(54) OPTOELECTRONIC SEMICONDUCTOR APPARATUS AND METHOD FOR PRODUCING AT LEAST ONE OPTOELECTRONIC SEMICONDUCTOR APPARATUS

(71) Applicant: ams-OSRAM International GmbH, Regensburg (DE)

(72) Inventor: Siegfried Herrmann, Neukirchen (DE)

(21) Appl. No.: 18/546,059

(22) PCT Filed: Feb. 2, 2022
(86) PCT No.: PCT/EP2022/052390

§ 371 Date: Aug. 10, 2023

(30) Foreign Application Priority Data
Feb. 18, 2021 (DE) 10 2021 201 588.3

(51) Int. Cl. H01L 33/62; H01L 25/075

(52) U.S. Cl. CPC H01L 33/62; H01L 25/0753; H01L 2933/0066

(57) ABSTRACT

In embodiments an optoelectronic semiconductor device includes a plurality of optoelectronic semiconductor chips, each having a first contact structure comprising a first contact element and a carrier having a holding structure, on which the optoelectronic semiconductor chips are each partly arranged and a second contact structure, wherein the first contact elements are movable by electrostatic forces between the first contact elements and the second contact structure in a direction of the carrier or away from the carrier and wherein the optoelectronic semiconductor chips are configured to switch between a first switching state and a second switching state by a movement.

### CROSS-REFERENCE TO RELATED APPLICATIONS

This patent application is a national phase filing under section 371 of PCT/EP2022/052390, filed Feb. 2, 2022, which claims the priority of German patent application 10 2021 201 588.3, filed Feb. 18, 2021, each of which is incorporated herein by reference in its entirety.

### TECHNICAL FIELD

An optoelectronic semiconductor device and a method for producing at least one optoelectronic semiconductor device are specified. Byway of example, the optoelectronic semiconductor device is a micro-LED device comprising a plurality of micro-LEDs, the dimensions and luminous width of which are in the micrometers range.

### BACKGROUND

Micro-LEDs are used in flat screens, for example, and form individual pixels therein. It is known to produce micro-LED arrangements monolithically in a batch method, wherein a semiconductor layer sequence on the basis of gallium nitride is formed epitaxially on a suitable substrate composed of sapphire or silicon. In this case, the individual light-emitting diodes (LEDs) are not divided, but rather maintained as a display matrix.

Furthermore, systems for dynamic light modulation are known, comprising a light source and, disposed downstream of the light source, a mirror matrix composed of tiltable mirror elements arranged in matrix form.

Attempts to integrate the light source into the mirror matrix and for example to mount LEDs onto such a movable system in order thus to modify an emission characteristic of a lighting system fail due to the mass inertia of the system, inter alia.

### SUMMARY

Embodiments provide a compact optoelectronic semiconductor device having a modifiable emission characteristic. Further embodiments provide a method for producing a compact optoelectronic semiconductor device having a modifiable emission characteristic.

In accordance with at least one embodiment of an optoelectronic semiconductor device, the latter comprises a plurality of optoelectronic semiconductor chips, each having a first contact structure comprising a first contact element. Furthermore, the optoelectronic semiconductor device has a carrier comprising a holding structure, on which the optoelectronic semiconductor chips are each partly arranged. Furthermore, the carrier comprises a second contact structure. The second contact structure can be provided for control and furthermore for electrical supply of the optoelectronic semiconductor chips. The carrier can contain or consist of a semiconductor material. By way of example, silicon is appropriate as carrier material.

The first contact elements are movable by electrostatic forces between the first contact elements and the second contact structure in the direction of the carrier or away from the carrier. The optoelectronic semiconductor chips can switch between a first switching state and a second switching state by means of the movement. In this case, a “switching state” denotes an electrical “on” or “off” state. In particular, the semiconductor chips are in a first stable end state in the first switching state, and in a second stable end state in the second switching state. By way of example, the first contact elements are situated at a greater distance from the carrier in the first stable end state than in the second stable end state.

By way of example, in the first switching state, no current flows through the semiconductor chips, and so the latter do not generate radiation if the semiconductor chips are radiation-emitting semiconductor chips. Furthermore, in the second switching state, current can flow through the semiconductor chips, and so the latter generate radiation if the semiconductor chips are radiation-emitting semiconductor chips.

The first contact elements or the first contact structure and also the second contact structure can each be formed from an electrically conductive material, for example from a metal or a metal compound.

By way of example, in order to attain the second switching state, that is to say for example in order to attain the switched-on state, the first contact elements are each at a first electrical potential, while the second contact structure is at a second electrical potential, different than the first, such that an electrostatic attraction takes place between each of the first contact elements and the second contact structure. In order to attain the first switching state, that is to say for example in order to attain the switched-off state, the respective first contact elements and the second contact structure can be at the same potential, such that no electrostatic attraction takes place. Switching between the first and second switching states is possible up to 5000 times per second.

In accordance with at least one embodiment, the optoelectronic semiconductor chips are arranged on the carrier in matrix form, that is to say in rows and columns.

The optoelectronic semiconductor chips are radiation-emitting semiconductor chips, for example, which are each provided for emitting electromagnetic radiation. In the present case, the term “electromagnetic radiation” is understood to mean in particular infrared, visible and/or ultraviolet electromagnetic radiation. During operation, at least part of the radiation can be emitted in each case at a front side of the optoelectronic semiconductor chips facing away from the carrier.

In accordance with at least one embodiment, the optoelectronic semiconductor chips each comprise a semiconductor body having a first and a second semiconductor region with different conductivities and an active zone arranged between the first and second semiconductor regions. Furthermore, the semiconductor chips can each have a carrier substrate, which is a growth substrate, for example, on which the semiconductor regions are deposited epitaxially. The carrier or growth substrate preferably comprises or consists of sapphire, SiC and/or GaN. A sapphire substrate is transparent to short-wave visible radiation, in particular in the blue to green range. Preferably, the optoelectronic semiconductor chips are substrateless semiconductor chips, in which the growth substrate has been thinned or detached.

Preferably, materials based on nitride compound semiconductors are appropriate for the semiconductor regions of the semiconductor bodies. In the present context, “based on nitride compound semiconductors” means that at least one semiconductor layer comprises a nitride III/V compound semiconductor material, preferably AlₙGaₘIn₁₋ₙ₋ₘN, where 0≤n≤1, 0≤m≤1 and n+m≤1. In this case, this material need not necessarily have a mathematically exact composition according to the above formula. Rather, it can comprise one or more dopants and additional constituents which substantially do not change the characteristic physical properties of the AlₙGaₘIn₁₋ₙ₋ₘN material. For the sake of simplicity, however, the above formula includes only the essential constituents of the crystal lattice (Al, Ga, In, N), even if these can be replaced in part by small amounts of further substances.

In accordance with at least one embodiment, the optoelectronic semiconductor chips are micro-LEDs. In this case, the semiconductor chips can have a first lateral dimension specified along a first lateral direction, said first lateral dimension being for example between 5 μm and 25 μm, in particular approximately 10 μm. Furthermore, a second lateral dimension specified along a second lateral direction can be equal in magnitude to the first lateral dimension and can be for example between 5 μm and 25 μm, in particular approximately 10 μm. Furthermore, a height of the optoelectronic semiconductor chips can be in each case 2 μm, for example. The height is determined along a vertical direction running transversely with respect to the first and second lateral directions.

In accordance with at least one embodiment of the optoelectronic semiconductor device, the first contact elements are electrically connectable to the second contact structure by a movement to the carrier and are electrically disconnectable from the second contact structure by a movement away from the carrier. Electric circuits in which the semiconductor chips are arranged can in each case be closed by the electrical connection of the first contact elements and the second contact structure. Correspondingly, electric circuits in which the semiconductor chips are arranged can in each case be interrupted by the electrical disconnection of the first contact elements and the second contact structure.

In accordance with at least one embodiment of the optoelectronic semiconductor device, the optoelectronic semiconductor chips are configured in elastic fashion, such that they deform upon the movement of the first contact elements.

In accordance with at least one embodiment of the optoelectronic semiconductor device, the holding structure has a plurality of holding elements. In this case, each semiconductor chip can be assigned at least one holding element. By way of example, the holding elements each have a columnar shape and rise from a main extension plane of the carrier. The holding elements can have at least approximately the shape of a parallelepiped, cone or truncated cone, or a pyramid or a truncated pyramid. A surface of the holding element which is arranged on a side facing away from the carrier can serve as a first bearing surface for the semiconductor chip.

Furthermore, the second contact structure can have a plurality of second contact elements, wherein each semiconductor chip is assigned at least one second contact element. The at least one second contact element can be assigned to the semiconductor chip one-to-one. The second contact elements can be separated from one another, that is to say for example laterally spaced apart from one another and/or electrically insulated from one another. Byway of example, the second contact elements have a rectangular, for example square, contour. The second contact elements can be switching electrodes. Alternatively, the second contact elements can be terminal electrodes for providing a supply voltage. Moreover, the first contact elements can be first terminal electrodes of the semiconductor chips. Furthermore, the first contact structures can each have a third contact element serving as a second terminal electrode of the semiconductor chip.

By means of the first and second contact elements, each semiconductor chip is individually switchable on and off, such that the optoelectronic semiconductor device enables dynamic control. Advantageously, each semiconductor chip can be controlled using just one line.

In accordance with at least one embodiment, each semiconductor chip is assigned at least one holding element and at least one second contact element, wherein the semiconductor chip is disposed downstream of the holding element and the second contact element proceeding from the carrier. By way of example, one part of the semiconductor chip bears on the first bearing surface of the holding element, while another part of the semiconductor chip, having the first contact element, is arranged above the second contact element in a vertical direction. In particular, a surface of the second contact element which is arranged on a side of the second contact element facing the semiconductor chip serves as a second bearing surface for the semiconductor chip when the first contact element contacts the second contact element, that is to say in particular when the semiconductor chip is in the second switching state.

In one advantageous configuration, the semiconductor chips are each regionally spaced apart from the carrier by at least one cavity. The at least one cavity can also exist when the first contact element contacts the second contact element, that is to say when the semiconductor chip is in the second stable state. The at least one cavity enables the movement of the first contact element, for example.

In accordance with at least one embodiment, the second contact elements are configured in elastic fashion, such that they deform in contact with the first contact elements.

In accordance with at least one embodiment, the semiconductor chips are arranged in movable fashion by means of the holding elements, such that they are movable in the direction of the carrier or away from the carrier, that is to say for example along the vertical direction. The holding elements can each have at least one movable connection means. The movable connection means is for example a rotary joint or a rotatable bar enabling a rotary movement in at least one plane.

Advantageously, an emission characteristic of the optoelectronic semiconductor device is adjustable or modifiable by the targeted switching on and off of optoelectronic semiconductor chips. By way of example, desired luminous patterns can be generated in a targeted manner by the regional switching on of optoelectronic semiconductor chips.

In accordance with at least one embodiment, the first contact structure has a plurality of first contact elements arranged on different sides of the optoelectronic semiconductor chip, wherein the semiconductor chip is tiltable toward the different sides by means of the first contact elements. In this case, the semiconductor chip can be assigned a plurality of second contact elements. The number of second contact elements here can correspond to the number of first contact elements. By way of example, the semiconductor chip can be tilted by an angle of approximately ±15°, for example from a plane parallel to the main extension plane of the carrier. The tilting in different directions allows different operating states.

In accordance with at least one embodiment, an emission direction of the emitted radiation is adjustable in a targeted manner by the tilting of the optoelectronic semiconductor chips.

Furthermore, a color locus of the emitted radiation can be adjusted in a targeted manner by the tilting of the optoelectronic semiconductor chips.

In accordance with at least one embodiment, the optoelectronic semiconductor device has a plurality of optical elements. By way of example, at least one of the optical elements can be a reflector that deflects the emitted radiation in a main emission direction. Moreover, at least one of the optical elements can be a stop. Furthermore, at least one optical element can be a light guide that guides the generated radiation from the semiconductor chip to a remote location.

Furthermore, the optoelectronic semiconductor device can have a plurality of conversion elements. By means of the conversion elements, it is possible in each case to convert part of the radiation generated by the semiconductor chips into radiation having a different, for example longer, wavelength.

The optical elements and/or conversion elements can each be disposed downstream of the semiconductor chips on different sides. Byway of example, a conversion element can surround the semiconductor chip in a ring-shaped or U-shaped manner in a plan view of the carrier. Furthermore, different conversion elements can be disposed downstream of the semiconductor chip on different sides, said conversion elements being provided for wavelength conversion into different wavelength ranges, such that radiation having different wavelengths can be generated on the different sides of the semiconductor chip simultaneously or at different times.

In accordance with at least one embodiment, the optoelectronic semiconductor device is operated in pulsed operation, for instance at up to 5000 Hz. Brightness and/or color locus of the emitted radiation can be suitably adjusted or modulated by this means.

In accordance with at least one embodiment, the optoelectronic semiconductor chips are arranged at a distance from one another which has values in the single-digit to double-digit micrometers range. The relatively small distance between the semiconductor chips makes it possible to achieve a high fill factor. The latter enables not only a high and uniform illumination of a projection area but also an almost pixel-free image.

The optoelectronic device can have a matrix composed of 4096×2160 pixels, wherein each pixel is formed by a semiconductor chip.

In accordance with at least one embodiment, the optoelectronic device has a housing, in which the semiconductor chips are arranged. The housing is provided for hermetically tightly enclosing the semiconductor chips and protecting them against environmental influences.

The optoelectronic semiconductor device has a compact size owing to the movable/deformable/tiltable semiconductor chips and the control possible as a result, which allow a transistor submount and a mirror matrix to be dispensed with, for example.

The method described below is suitable for producing one optoelectronic device or a plurality of optoelectronic devices of the type mentioned above. Features described in connection with the optoelectronic device can therefore be used for the method as well, and vice versa.

In accordance with at least one embodiment of a method for producing at least one optoelectronic semiconductor device, this method comprises:
providing a semiconductor wafer for forming semiconductor chips, each having a first contact structure comprising a first contact element,
providing a carrier comprising a holding structure and a second contact structure,
connecting the semiconductor wafer and the carrier by means of a connection layer,
forming semiconductor chips by structuring the semiconductor wafer, such that the semiconductor chips are each partly arranged on the holding structure,
removing the connection layer.

The method steps are preferably carried out in the order specified.

In accordance with at least one embodiment of the method, the semiconductor wafer is arranged relative to the carrier such that the first contact elements each laterally overlap the second contact structure.

In accordance with at least one embodiment, the connection layer contains or consists of at least one of the following materials: plastic, semiconductor, for example amorphous silicon.

The optoelectronic device is particularly suitable for display devices, projection system such as, for example, virtual reality projectors, vehicle headlights or consumer electronics such as video glasses, for example.

### BRIEF DESCRIPTION OF THE DRAWINGS

Further advantages, advantageous embodiments and developments will become apparent from the exemplary embodiments described below in association with the figures.

FIG. 1A shows a schematic perspective view of a first exemplary embodiment of a relatively large detail of an optoelectronic semiconductor device;

FIG. 1B shows a schematic perspective view of a relatively small detail of the optoelectronic semiconductor device in accordance with the first exemplary embodiment;

FIG. 1C shows a schematic side view of the detail illustrated in FIG. 1B of the optoelectronic semiconductor device in accordance with the first exemplary embodiment in a first stable end state;

FIG. 1D shows a schematic plan view of a holding element of the optoelectronic semiconductor device in accordance with the first exemplary embodiment;

FIG. 1E shows a schematic side view of the detail illustrated in FIG. 1B of the optoelectronic semiconductor device in accordance with the first exemplary embodiment in a second stable end state;

FIG. 2 shows a schematic side view of a detail of an optoelectronic semiconductor device in accordance with a second exemplary embodiment in a first stable end state;

FIG. 3 shows a schematic plan view of a detail of an optoelectronic semiconductor device in accordance with a third exemplary embodiment;

FIG. 4 shows a schematic side view of a detail of an optoelectronic semiconductor device in accordance with a fourth exemplary embodiment in a second stable end state;

FIGS. 5 to 7 each show schematic plan views of a detail of an optoelectronic semiconductor device in accordance with fifth, sixth and seventh exemplary embodiments;

FIG. 8 shows a schematic perspective view of a detail of an optoelectronic semiconductor device in accordance with an eighth exemplary embodiment; and

FIGS. 9A to 9D show schematic illustrations of method steps of a method in accordance with one exemplary embodiment.

### DETAILED DESCRIPTION OF ILLUSTRATIVE EMBODIMENTS

In the exemplary embodiments and figures, elements that are identical, of identical type or act identically may each be provided with the same reference signs. The illustrated elements and their size relationships among one another should not necessarily be regarded as true to scale; rather, individual elements may be illustrated with an exaggerated size in order to enable better illustration and/or in order to afford a better understanding.

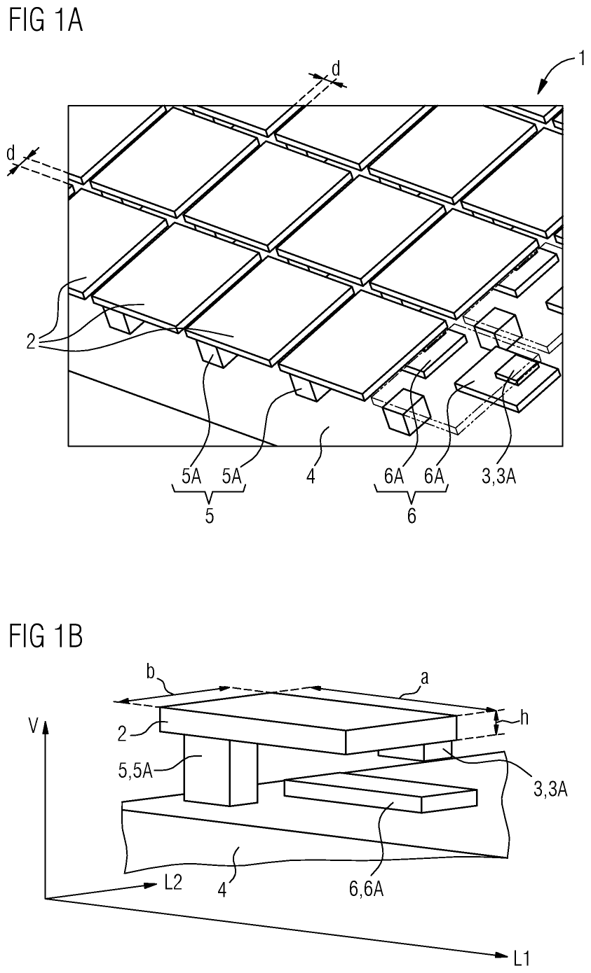

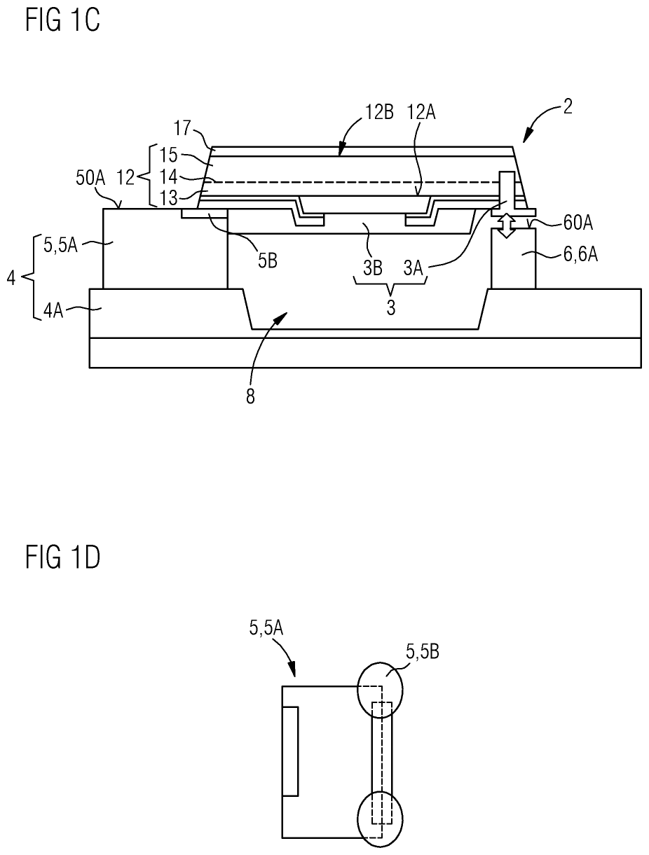

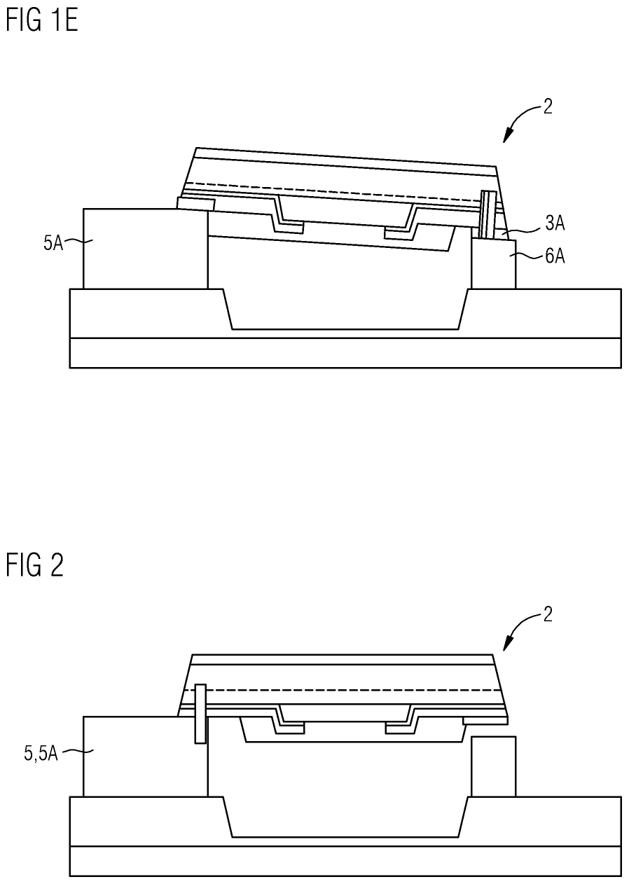

FIG. 1A to 1E illustrate various views of a first exemplary embodiment of an optoelectronic semiconductor device 1 or details thereof. The optoelectronic semiconductor device 1 is a radiation-emitting device provided for the emission of electromagnetic radiation. In the present case, the term “electromagnetic radiation” is understood to mean, in particular, infrared, visible and/or ultraviolet electromagnetic radiation.

The optoelectronic semiconductor device 1 comprises a plurality of optoelectronic semiconductor chips 2, each having a first contact structure 3 comprising a first contact element 3A.

Furthermore, the optoelectronic semiconductor device 1 has a carrier 4 comprising a holding structure 5, on which the optoelectronic semiconductor chips 2 are each partly arranged, and a second contact structure 6. The second contact structure 6 can be provided for control and furthermore for electrical supply of the optoelectronic semiconductor chips 2. The carrier 4 can contain or consist of a semiconductor material. By way of example, silicon is appropriate as carrier material. The optoelectronic semiconductor chips 2 are arranged on the carrier 4 in matrix form, that is to say in rows and columns.

The optoelectronic semiconductor chips 2 each comprise a semiconductor body 12 having a first semiconductor region 13, a second semiconductor region 15 and an active zone 14 arranged between the first and second semiconductor regions 13, 15. By way of example, the first semiconductor region 13 is a p-doped semiconductor region, and the second semiconductor region 15 is an n-doped semiconductor region. The first semiconductor region 13 can be arranged on a side of the active zone 14 facing the carrier 4, and the second semiconductor region 15 can be arranged on a side of the active zone 14 facing away from the carrier 4. The first contact element 3A is arranged on the side of a first main surface 12A of the semiconductor body 12, said first main surface facing the carrier 4, and can extend from there into the semiconductor body 12. A second main surface 12B of the semiconductor body 12, said second main surface facing away from the carrier 4, is arranged on a radiation exit side of the semiconductor chip 2, at which at least part of the radiation can be emitted from the semiconductor chip 2.

Furthermore, the semiconductor chips 2 each have a carrier substrate 17, which is a growth substrate, for example, and on which the semiconductor body 12 is deposited epitaxially, for example. Preferably, the optoelectronic semiconductor chips 2 are substrateless semiconductor chips, in which the carrier substrate 17 has been thinned or completely detached.

Preferably, materials based on nitride compound semiconductors are appropriate for the semiconductor body 12. In the present context, “based on nitride compound semiconductors” means that at least one layer of the semiconductor body 12 comprises a nitride III/V compound semiconductor material, preferably AlₙGaₘIn₁₋ₙ₋ₘN, where 0≤n≤1, 0≤m≤1 and n+m≤1. In this case, this material need not necessarily have a mathematically exact composition according to the above formula. Rather, it can comprise one or more dopants and additional constituents which substantially do not change the characteristic physical properties of the AlₙGaₘIn₁₋ₙ₋ₘN material. For the sake of simplicity, however, the above formula includes only the essential constituents of the crystal lattice (Al, Ga, In, N), even if these can be replaced in part by small amounts of further substances.

Byway of example, the optoelectronic semiconductor chips 2 are micro-LEDs. In this case, the semiconductor chips 2 have a first lateral dimension a specified along a first lateral direction L1, said first lateral dimension being for example between 5 μm and 25 μm, in particular approximately 10 μm. Furthermore, a second lateral dimension b specified along a second lateral direction L2 can be equal in magnitude to the first lateral dimension a and can be for example between 5 μm and 25 μm, in particular approximately 10 μm. Furthermore, a height h of the optoelectronic semiconductor chips 2 can be in each case 2 μm, for example. The height h is determined along a vertical direction V running transversely with respect to the first and second lateral directions L1, L2.

The first contact elements 3A of the first contact structures 3 can be first terminal electrodes of the semiconductor chips 2. Furthermore, the first contact structures 3 can each have a third contact element 3B serving as a second terminal electrode of the semiconductor chip 2. However, it is also possible for the first contact elements 3A to be provided only for establishing a physical contact with the second contact structure 6. By way of example, the first contact elements 3A are electrically insulated from the semiconductor body 12.

The first contact elements 3A or the first contact structure 3 and also the second contact structure 6 can each be formed from an electrically conductive material, for example from a metal or a metal compound.

The holding structure 5 of the carrier 4 has a plurality of holding elements 5A projecting in columnar fashion from a main extension plane of the carrier 4. Byway of example, the main extension plane is arranged parallel to a plane spanned by the first lateral direction L1 and the second lateral direction L2. The holding elements 5A have at least approximately the shape of a parallelepiped. The holding elements 5A can be separate elements arranged on a main body 4A of the carrier 4. Alternatively, the holding elements 5A can be formed integrally with the main body 4A.

In the case of the first exemplary embodiment, each semiconductor chip 2 is assigned exactly one holding element 5A. A surface 50A of the holding element 5A which is arranged on a side facing away from the carrier 4 can serve as a first bearing surface for the semiconductor chip 2. A first part, for example a first corner region, of the semiconductor chip 2 bears on the first bearing surface. The first contact element 3A is situated in a second part, for example a second corner region diagonally opposite the first corner region, of the semiconductor chip 2.

The second contact structure 6 has a plurality of second contact elements 6A, each semiconductor chip 2 being assigned exactly one second contact element 6. The second contact elements 6A are laterally spaced apart from one another and electrically insulated from one another. A surface 60A of the second contact element 6A which is arranged on a side of the second contact element 6A facing the semiconductor chip 2 serves as a second bearing surface for the semiconductor chip 2.

The semiconductor chips 2 are each regionally spaced apart from the carrier 4 by a cavity 8. The cavity 8 is delimited laterally by the holding element 5A and the second contact element 6A. Furthermore, the cavity 8 can extend right into the main body 4A. The cavity 8 makes possible in each case the movement of the first contact element 3A.

The semiconductor chips 2 are arranged in movable fashion by means of the holding elements 5A, such that they are movable in the direction of the carrier 4 or away from the carrier 4. In this case, the holding elements 5A have a movable connection means 5B. The movable connection means 5B is a rotary joint (cf. FIG. 1D), for example, which enables a movement of the semiconductor chip 2 along the vertical direction V.

The first contact elements 3A are movable by electrostatic forces between the first contact elements 3A and the second contact structure 6 or the second contact elements 6A (cf. double-headed arrow in FIG. 1C) in the direction of the carrier 4 or away from the carrier 4. By means of the upward and downward movement, the optoelectronic semiconductor chips 2 can switch between a first switching state and a second switching state. In this case, a “switching state” denotes an electrical “on” or “off” state. In particular, the semiconductor chips 2 are in a first stable end state in the first switching state, and in a second stable end state in the second switching state.

By way of example, in order to attain the second switching state, for instance in order to switch on the semiconductor chips 2, the first contact elements 3A are each at a first electrical potential, while the second contact structure 6 is at a second electrical potential, different than the first, such that an electrostatic attraction takes place between each of the first contact elements 3A and the second contact structure 6 (cf. FIG. 1E). In order to attain the first switching state, for instance in order to switch off the semiconductor chips 2, the respective first contact elements 3A and the second contact structure 6 can be brought to the same potential, such that there is no longer any electrostatic attraction (cf. FIG. 1C). In this case, it is possible to switch between the first and second stable states up to 5000 times per second. In the second switching state or in the second stable end state, the contact element 3A is situated closer to the carrier 4 than in the first switching state or the first stable end state.

In the second switching state, an electric current can flow through the optoelectronic semiconductor chips 2 and radiation can be generated. Correspondingly, in the first switching state, no electric current flows through the semiconductor chips 2, and so the latter do not generate radiation.

By means of the first and second contact elements 3A, 6A, each semiconductor chip 2 is individually switchable on and off, such that the optoelectronic semiconductor device 1 enables dynamic control.

The optoelectronic semiconductor chips 2 are arranged at a distance d from one another which has values in the single-digit to double-digit micrometers range. The relatively small distance d between the semiconductor chips 2 makes it possible to achieve a high fill factor.

In the case of the exemplary embodiments illustrated in FIGS. 2 to 8, principally the differences with respect to the first exemplary embodiment will be discussed. For the rest, all explanations already given in connection with the first exemplary embodiment are applicable.

In the case of the second exemplary embodiment illustrated in FIG. 2, the semiconductor chips 2 are each fixedly connected to the holding element 5A. In this case, the optoelectronic semiconductor chips 2 are configured in elastic fashion, such that they deform upon the movement of the first contact elements 3A.

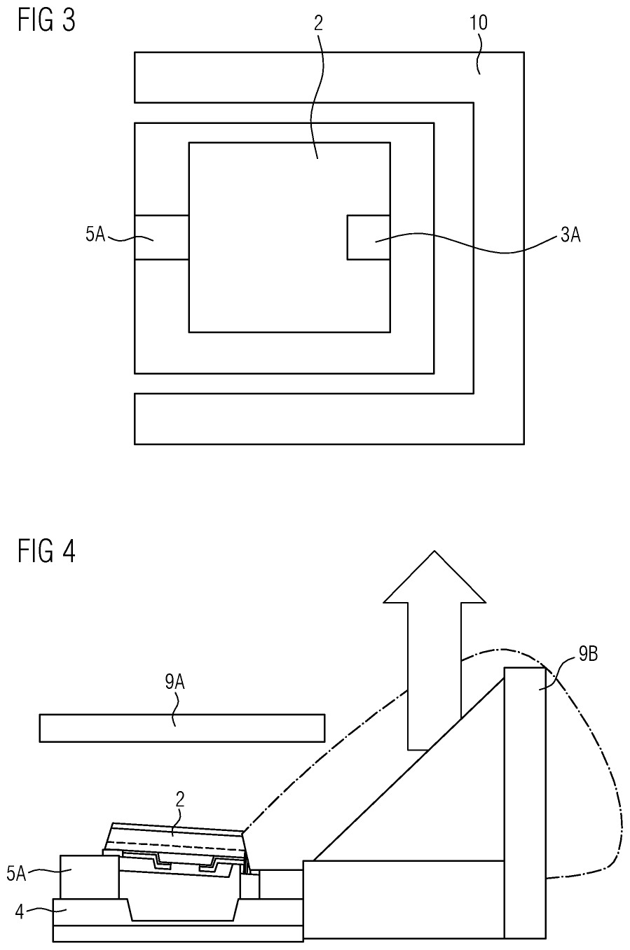

In the case of the third exemplary embodiment illustrated in FIG. 3, the optoelectronic semiconductor device has conversion elements 10 disposed downstream of the semiconductor chips 2 in each case on three different sides. The semiconductor chips 2 here are each surrounded by a conversion element 10 in a U-shaped manner in a plan view of the carrier 4. The side on which the holding element 5A is arranged remains free of the conversion element 10. By means of the conversion elements 10, in each case at least part of the radiation generated by the semiconductor chips 2 can be converted into radiation having a different wavelength. By superposing the radiation portions having different wavelengths, it is possible for mixed-colored light, for example white light, to be emitted by the optoelectronic semiconductor device.

In the case of the fourth exemplary embodiment illustrated in FIG. 4, the optoelectronic semiconductor device has a plurality of different optical elements 9A, 9B, wherein for example each semiconductor chip 2 is assigned at least one first optical element 9A and one second optical element 9B. The first optical element 9A is a stop disposed downstream of the semiconductor chip 2 on the radiation exit side. The second optical element 9B is a reflector disposed downstream of the semiconductor chip 2 laterally. The emitted radiation is attenuated by means of the first optical element 9A. The impinging radiation is deflected in a preferred direction (indicated by the arrow) by means of the second optical element 9B. The arrangement comprising the first and second optical elements 9A, 9B enables a modification of the emission, for example of the emission direction.

In the case of the fifth exemplary embodiment illustrated in FIG. 5, the semiconductor chips 2 each have a first contact structure 3 having a plurality of first contact elements 3A arranged on three different sides of the optoelectronic semiconductor chip 2, wherein the semiconductor chip 2 is tiltable toward the three different sides by means of the first contact elements 3A. By way of example, the semiconductor chip 2 can be tilted by an angle of approximately ±150 from a plane running parallel to the main extension plane of the carrier. On each of the three sides an optical element 9 is disposed downstream of the semiconductor chip 2. The optical elements 9 can be stops. With the optical elements 9 and the corresponding first contact elements 3A, the radiation emitted by the semiconductor chip 2 can be emitted in different spatial directions depending on the switching state.

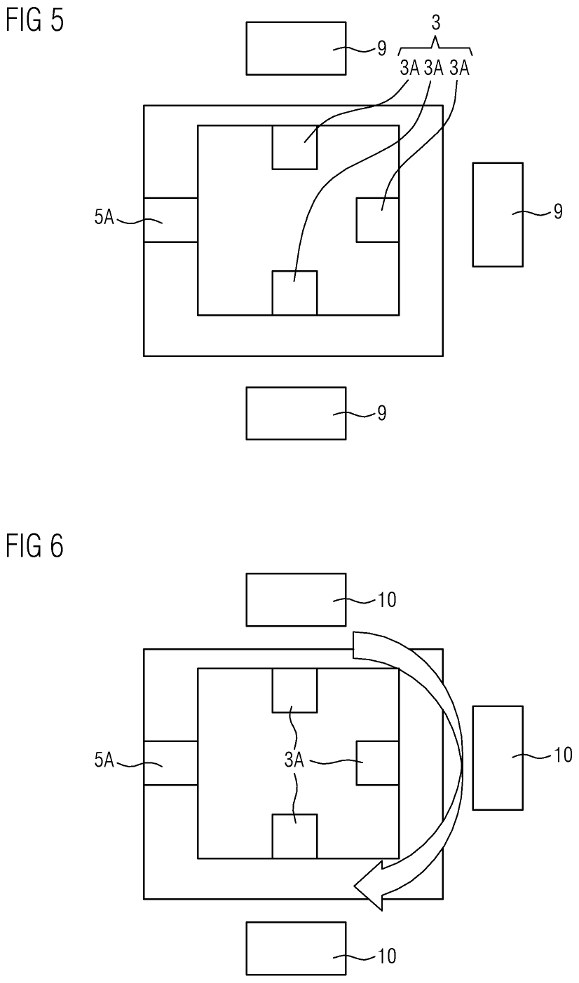

The sixth exemplary embodiment illustrated in FIG. 6 is like the fifth exemplary embodiment. However, a conversion element 10 is disposed downstream of the semiconductor chips 2 on each of the three sides. The three conversion elements 10 can be provided for at least partly converting the radiation emitted by the semiconductor chip 2 into radiation in different wavelength ranges, for example into red, green and blue light. By means of the conversion elements 10 and the corresponding first contact elements 3, depending on the switching state, the radiation emitted at the location of the semiconductor chip 2 can have different cover loci. The color locus and/or the brightness can be adjusted by means of suitable pulsed operation.

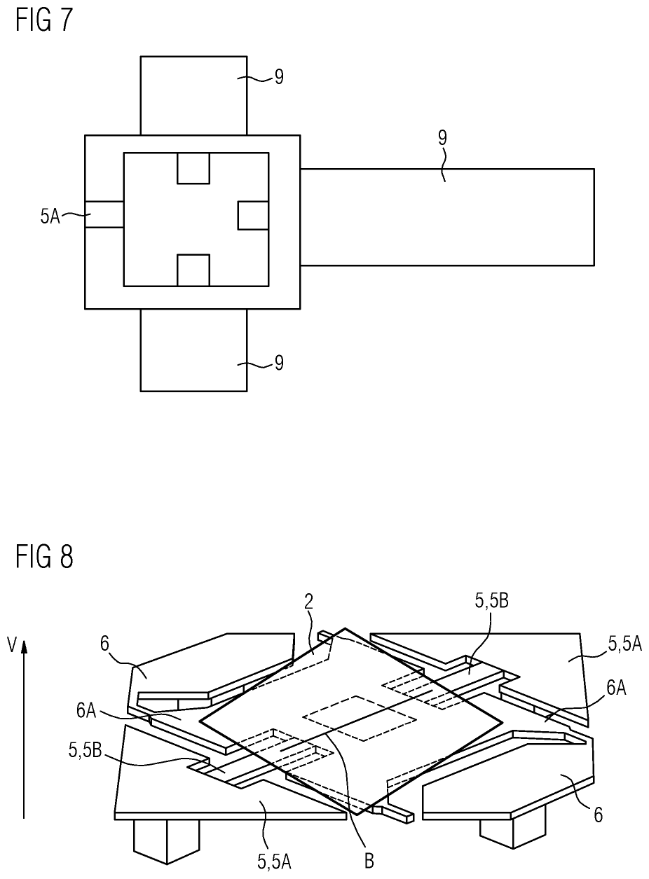

The seventh exemplary embodiment illustrated in FIG. 7 is like the fifth exemplary embodiment. However, the optical elements 9 are light guides. By means of the optical elements 9 and the corresponding first contact elements 3A, depending on the switching state, the radiation emitted at the location of the semiconductor chip 2 can be guided to different remote locations.

In the case of the exemplary embodiment illustrated in FIG. 8, the holding structure 5 of the optoelectronic semiconductor device has two holding elements 5A situated opposite one another for each semiconductor chip 2, said holding elements each having a movable connection means 5B. The semiconductor chip 2 is connected to the connection means 5B on two sides situated opposite one another. The second contact element 6A extends between the two holding elements 5A transversely with respect to an imaginary connection line B between the two connection means 5B.

The movable connection means 5B enable a vertical movement of the semiconductor chip 2 along the vertical direction V. Additionally or alternatively, the movable connection means 5B can be provided for a rotational movement or tilting about the connection line B.

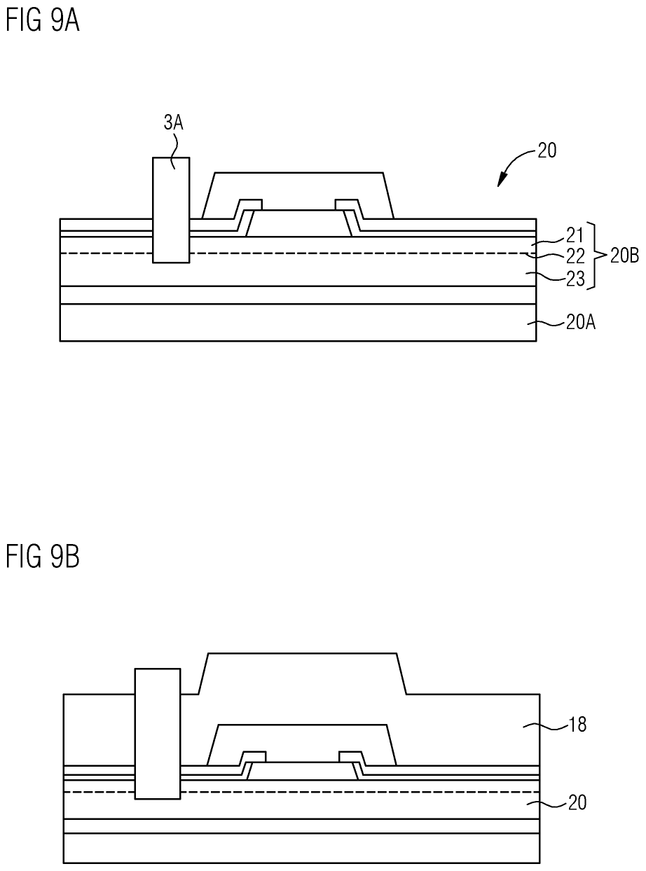

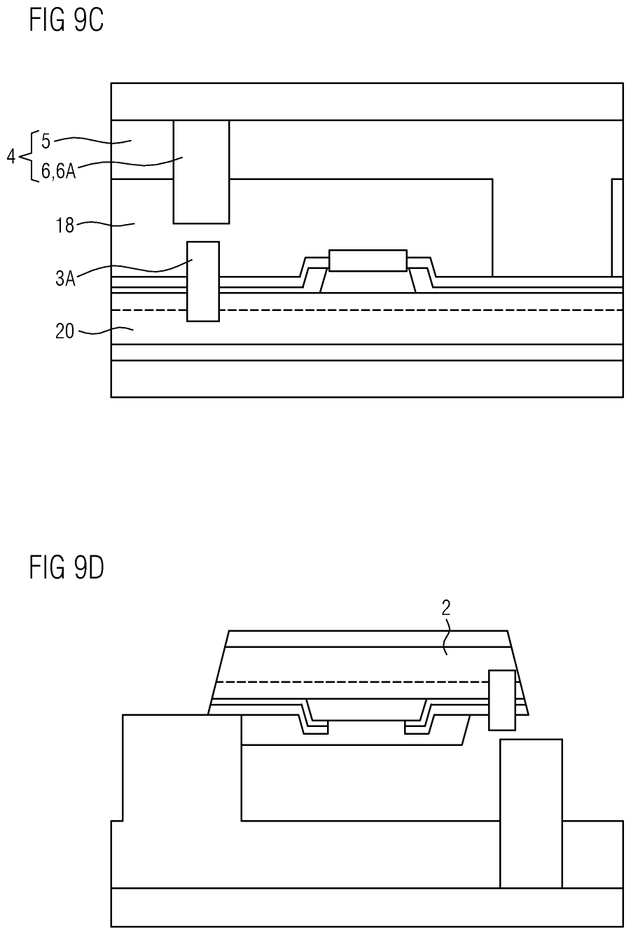

One exemplary embodiment of a method for producing at least one optoelectronic semiconductor device will be described in association with FIGS. 9A to 9D.

In this case, in order to form semiconductor chips 2, a semiconductor wafer 20 is provided (cf. FIG. 9A). The semiconductor wafer 20 comprises a substrate 20A and also a semiconductor layer sequence 20B, which is arranged, for example grown epitaxially, on the substrate 20A. The semiconductor layer sequence 20B comprises a first semiconductor layer 21 for producing the first semiconductor region 13 of each semiconductor chip 2, an active layer 22 for producing the active zone 14 of each semiconductor chip 2, and a second semiconductor layer

23 for producing the second semiconductor region 15 of each semiconductor chip 2. Furthermore, the semiconductor wafer 20 comprises first contact elements 3A, which are each part of the first contact structure 3 in the finished semiconductor chip 2.

A connection layer 18 is arranged on the semiconductor wafer 20 (cf. FIG. 9B). The connection layer 18 contains for example a material that can easily be removed later. For example, a plastic material or a semiconductor material such as amorphous silicon, for instance, is appropriate for the connection layer 18.

Furthermore, a carrier 4 comprising a second holding structure 5 and a second contact structure 6 is provided (cf. FIG. 9C). The carrier 4 is connected to the semiconductor wafer 20 by means of the connection layer 18. The carrier 4 is arranged relative to the semiconductor wafer 20 such that the first contact elements 3A each overlap the second contact structure 6 laterally. By way of example, the carrier 4 is arranged relative to the semiconductor wafer 20 such that each first contact element 3A overlaps a second contact element 6A laterally.

After connection to the carrier 4, the semiconductor wafer 20 is structured to form semiconductor chips 2, each partly arranged on the holding structure 5. The connection layer 18 is then removed (cf. FIG. 9D).

The invention is not restricted to the exemplary embodiments by the description on the basis of said exemplary embodiments. Rather, the invention encompasses any novel feature and also any combination of features, which in particular includes any combinations of features in the patent claims, even if this feature or this combination itself is not explicitly specified in the patent claims or exemplary embodiments.

1-15. (canceled)

16. An optoelectronic semiconductor device comprising:
a plurality of optoelectronic semiconductor chips, each having a first contact structure comprising a first contact element; and
a carrier comprising:
a holding structure, on which the optoelectronic semiconductor chips are each partly arranged; and
a second contact structure,
wherein the first contact elements are movable by electrostatic forces between the first contact elements and the second contact structure in a direction of the carrier or away from the carrier, and
wherein the optoelectronic semiconductor chips are configured to switch between a first switching state and a second switching state by a movement.

17. The optoelectronic semiconductor device as claimed in claim 16, wherein the first contact elements are electrically connectable to the second contact structure by the movement to the carrier and are electrically disconnectable from the second contact structure by the movement away from the carrier.

18. The optoelectronic semiconductor device as claimed in claim 16, wherein the optoelectronic semiconductor chips are elastic such that they deform upon the movement of the first contact elements.

19. The optoelectronic semiconductor device as claimed in claim 16, wherein the holding structure comprises a plurality of holding elements and the second contact structure comprises a plurality of second contact elements, wherein each semiconductor chip is assigned to at least one holding element and to at least one second contact element, and wherein each semiconductor chip is disposed downstream of a respective holding element and a respective second contact element proceeding from the carrier.

20. The optoelectronic semiconductor device as claimed in claim 19, wherein the semiconductor chips are arranged in a movable fashion by the holding elements such that they are movable in the direction of the carrier or away from the carrier.

21. The optoelectronic semiconductor device as claimed in claim 20, wherein each of the holding elements has at least one movable connection means.

22. The optoelectronic semiconductor device as claimed in claim 19, wherein the second contact elements are elastic such that they deform in contact with the first contact elements.

23. The optoelectronic semiconductor device as claimed in claim 22, wherein the semiconductor chips are arranged in a movable fashion by the holding elements such that they are movable in the direction of the carrier or away from the carrier.

24. The optoelectronic semiconductor device as claimed in claim 23, wherein each of the holding elements has at least one movable connection means.

25. The optoelectronic semiconductor device as claimed in claim 16, wherein the first contact structure has a plurality of first contact elements arranged on different sides of the optoelectronic semiconductor chip, and wherein the semiconductor chip is tiltable toward the different sides by the first contact elements.

26. The optoelectronic semiconductor device as claimed in claim 25, wherein the optoelectronic semiconductor chip is configured to emit radiation, and wherein a color locus of the emitted radiation is adjustable in a targeted manner by tilting of the optoelectronic semiconductor chips.

27. The optoelectronic semiconductor device as claimed in claim 25, wherein the optoelectronic semiconductor device is configured to emit radiation, and wherein an emission direction of the emitted radiation is adjustable in a targeted manner by tilting of the optoelectronic semiconductor chips.

28. The optoelectronic semiconductor device as claimed in claim 27, wherein a color locus of the emitted radiation is adjustable in a targeted manner by the tilting of the optoelectronic semiconductor chips.

29. The optoelectronic semiconductor device as claimed in claim 16, further comprising a plurality of optical elements and/or conversion elements, each disposed downstream of the semiconductor chips on different sides.

30. The optoelectronic semiconductor device as claimed in claim 16, wherein the carrier contains a semiconductor material.

31. A method for producing at least one optoelectronic semiconductor device as claimed in claim 16, the method comprising:
providing a semiconductor wafer for forming semiconductor chips, each semiconductor chip having the first contact structure comprising the first contact element;
providing the carrier comprising the holding structure and the second contact structure;
connecting the semiconductor wafer and the carrier by a connection layer;
forming the semiconductor chips by structuring the semiconductor wafer such that the semiconductor chips are each partly arranged on the holding structure; and
removing the connection layer.

32. The method as claimed in claim 31, wherein the connection layer contains at least plastic or amorphous silicon.

33. The method as claimed in claim 31, wherein the semiconductor wafer is arranged relative to the carrier such that the first contact elements each laterally overlap the second contact structure.

34. The method as claimed in claim 33, wherein the connection layer contains at least plastic or amorphous silicon.
